(19) United States
(12) Patent Application Publication
(10) Pub. No.: US 2026/0044012 A1
(43) Pub. Date: Feb. 12, 2026

(54) NEAR EYE DISPLAY METROLOGY INSTRUMENT

(71) Applicant: Novanta Corporation, Bedford, MA (US)

(72) Inventor: Matt Falanga, Liverpool, NY (US)

(73) Assignee: Novanta Corporation, Bedford, MA (US)

(21) Appl. No.: 19/291,907

(22) Filed: Aug. 6, 2025

Related U.S. Application Data
(60) Provisional application No. 63/679,836, filed on Aug. 6, 2024.

(51) Int. Cl. G02B 27/01; G01R 33/12

(52) U.S. Cl. CPC G02B 27/0179; G01R 33/1253; G02B 27/0101; G02B 2027/011; G02B 2027/0138; G02B 2027/014

(57) ABSTRACT

A near eye display metrology device that is compact and will work with longer focal lengths such as those needed for windshield heads-up-display (HUD) and augmented reality heads-up-display (AR-HUD). The device includes an XY galvanometer having a pair of mirrors to controllably deflect an expanded beam traveling along the optical axis in an X dimension and in the Y dimension. An auto-focus assembly is positioned along the optical axis and a controller is coupled to the motors and programmed to correct for any distortions in the device and to control the auto-focus assembly. At least one aperture is positioned along the optical axis and oriented to reduce the measurement field angle of the device and to block any out-of-focus illumination. A spectrograph including a component configured to disperse light onto an imager is used to obtain test results.

### CROSS-REFERENCE TO RELATED APPLICATIONS

The present application claims priority to U.S. Provisional Application No. 63/679,836, filed on Aug. 6, 2024, hereby incorporated by reference in its entirety.

### BACKGROUND OF THE INVENTION

### 1. Field

The present disclosure relates to metrology instruments and, more particularly, to a compact XY galvanometer for use in testing a near eye display.

### 2. Description of the Related Art

Conventional approaches for photometric measurements of near eye displays are limited by magnification, which reduces etendue if the focal length of the near-eye display increases. In some virtual display applications, such as windshield heads-up-display (HUD) and augmented reality heads-up-display (AR-HUD), the focal lengths may be hundreds of millimeters rather than the tens of millimeters that are more common in, for example, a pancake lens. Systems that employ Fourier optics, such as WO2021170960, and/or a conoscope, such as WO2022204029, are further limited by the diameter and length of the lenses that are necessary and sufficient for FOV measurements. Although there are 6-axis platforms, such as that seen in U.S. Pat. No. 10,972,721, these systems are of limited use in connection with HUD and AR-HUD due to the amount of space required for staging and motion. Accordingly, there is a need in the art for a metrology instrument that can be used for near eye displays having the longer focal lengths such as those associated with windshield HUD and AR-HUD.

### BRIEF SUMMARY OF THE INVENTION

The present invention provides a device that can be used for near eye display metrology that will work with longer focal lengths without employing bulky mechanisms. The device is positioned at the eye point of the display under test, where the virtual image field of view can be viewed uniformly (also known as the eyebox). When the device is actuated, a controller executes the scanning process to rapidly scan a focal point of the field of view at multiple virtual image distances (as seen through the near eye display optics), and the readings are collected and processed by the imager. Each reading corresponds to a field point in the field of view, which is collected sequentially to form an image. The measured image is used to calculate two-dimensional luminance, chromaticity, spectral radiance, spatial contrast, and resolution.

In one embodiment, the invention is a metrology instrument for a near eye display having an XY galvanometer having a pair of mirrors oriented along an optical axis, wherein each of the mirrors is associated with one of a pair of motors so that one of the pair of mirrors can controllably deflect a beam traveling along the optical axis in an X dimension, and the other of the pair of mirrors can controllably deflect the beam in the Y dimension. An autofocus mechanism is positioned along the optical axis. A controller is coupled to the pair of motors that is programmed to correct for any distortions in the XY galvanometer and to control the auto-focus assembly. At least one aperture is positioned along the optical axis and oriented to reduce a measurement field angle of the device and to block any out-of-focus illumination. An eyepiece is positioned along the optical axis. A spectrograph is positioned along the optical axis for measuring a plurality of spectral characteristics of the beam. The spectrograph may include an imager for capturing a digital image of the beam. The XY galvanometer may have a field of view of at least twenty degrees along a horizontal axis. The XY galvanometer may have a field of view of at least 6.6 degrees along a vertical axis.

In another embodiment, the invention is a method of performing photometric measurements of a near eye display. In a first step, the method comprises positioning an XY galvanometer at an eye point of the near eye display, wherein the X galvanometer has a pair of mirrors oriented along an optical axis and intersecting the eye point to receive a beam from the near eye display, wherein each of the mirrors is associated with one of a pair of motors so that one of the pair of mirrors can controllably deflect the beam traveling along the optical axis in an X dimension, and the other of the pair of mirrors can controllably deflect the beam in the Y dimension. The method includes focusing the beam with an autofocus mechanism. The method includes correcting for any distortions in the XY galvanometer. The method includes reducing a measurement field angle and blocking any out-of-focus illumination with an aperture. The method include capturing the beam from the near eye display with spectrograph to measure a plurality of spectral characteristics of the beam. The method may further include the step of capturing a digital image of the beam with an imager associated with the spectrograph. The XY galvanometer may have a field of view of at least twenty degrees along a horizontal axis. The XY galvanometer may have a field of view of at least 6.6 degrees along a vertical axis.

### BRIEF DESCRIPTION OF THE SEVERAL VIEWS OF THE DRAWING(S)

The present invention will be more fully understood and appreciated by reading the following Detailed Description in conjunction with the accompanying drawings, in which:

FIG. 1 is a perspective view of a metrology instrument according to the present invention.

FIG. 2 is a top plan of a metrology instrument according to the present invention.

FIG. 3 is a side view of a metrology instrument according to the present invention.

FIG. 4 is a schematic of the components of a metrology instrument according to the present invention.

FIG. 5 is a schematic of testing using a metrology instrument according to the present invention.

FIG. 6 is a schematic of a first step when testing a near-eye display with a metrology instrument according to the present invention.

FIG. 7 is a schematic of another step when testing a near-eye display with a metrology instrument according to the present invention.

FIG. 8 is a schematic of a further step when testing a near-eye display with a metrology instrument according to the present invention.

FIG. 9 is a schematic of a scanning of a near-eye display with a metrology instrument according to the present invention.

FIG. 10 is another schematic of a scanning of a near-eye display with a metrology instrument according to the present invention.

FIG. 11 is a further schematic of a scanning of a near-eye display with a metrology instrument according to the present invention.

FIG. 12 is an additional schematic of a scanning of a near-eye display with a metrology instrument according to the present invention.

FIG. 13 is a flowchart of a method of using a metrology instrument to measure the spectral characteristics of a near eye display according to the present invention.

FIG. 14 is a pair of images showing pupil shift and focus compensation according to the present invention.

### DETAILED DESCRIPTION OF THE INVENTION

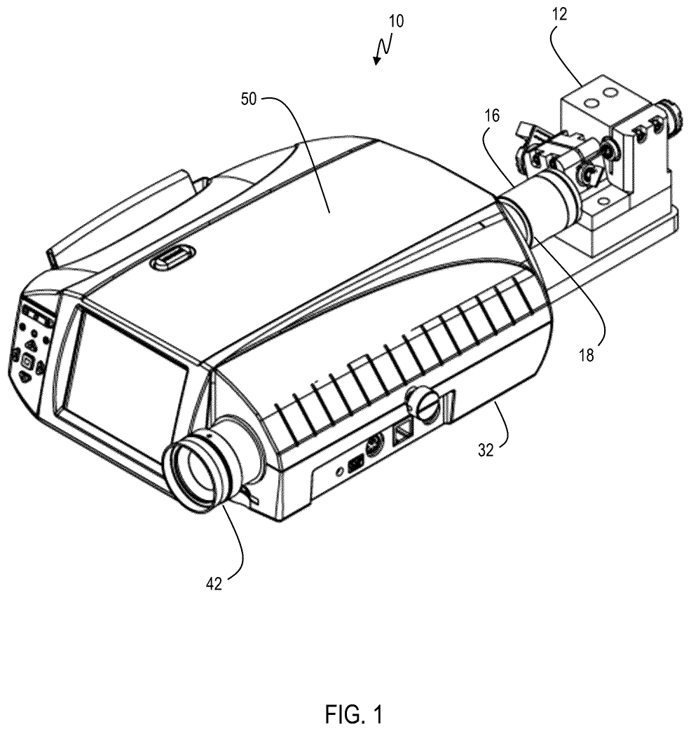

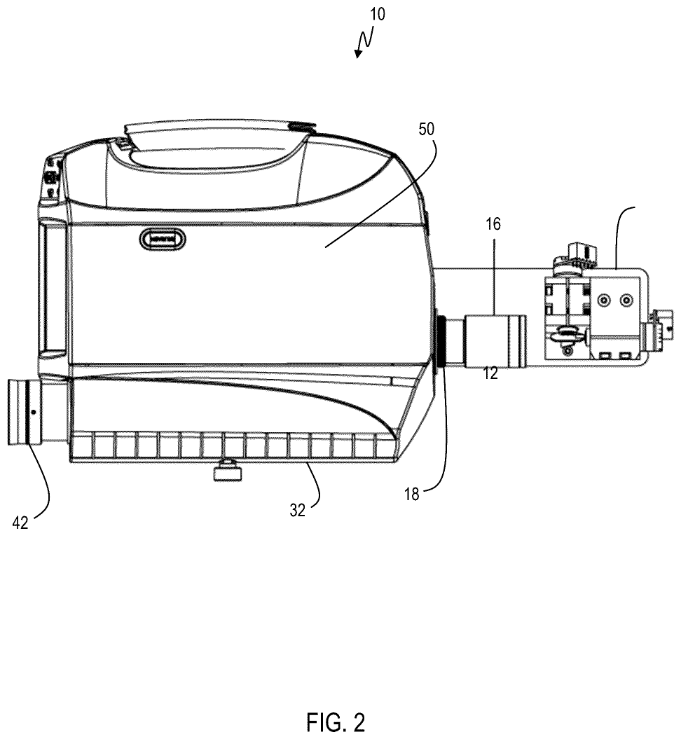

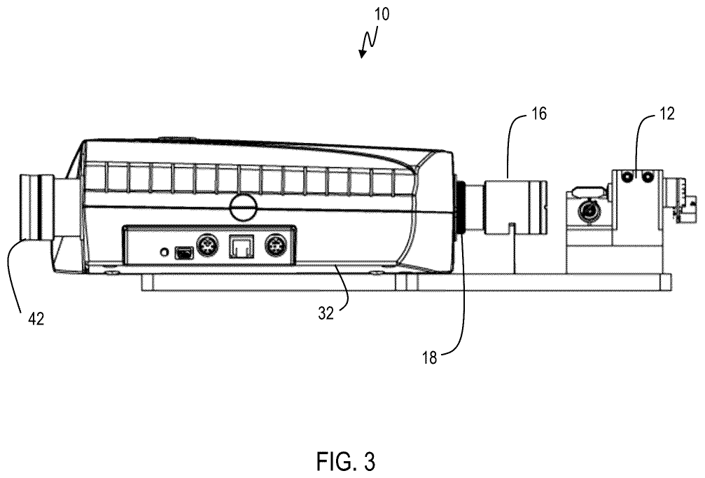

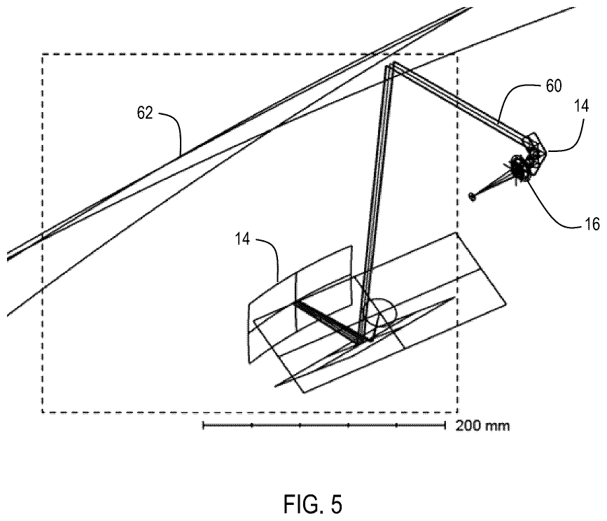

Referring to the figures, wherein like numerals refer to like parts throughout, there is seen in FIGS. 1 through 3, a metrology instrument 10 having compact XY galvanometer set 12 that may be situated within the eyebox of a near eye display 14, as illustrated in FIGS. 5, for performing metrology and testing of near eye display 14 with an associated spectrometer 50 that receives the scanned optical beam output from XY galvanometer set 12. XY galvanometer set 12 is suitable for use with pupil diameters in the range of 2-5 mm that are common to near-eye display specifications, such as those established in Section 19.2 of the Information Display Measurements Standard Version 1.2. The optical scan angles of XY galvanometer set 12 in this range permit field of view (FOV) measurements up to +/−40 deg in the horizontal axis of the ocular. An auto-focus mechanism 16 positioned at the output of XY galvanometer set 12 permits multiple virtual image distances. An aperture wheel 18 may be used to block out-of-focus light and further reduce field angle.

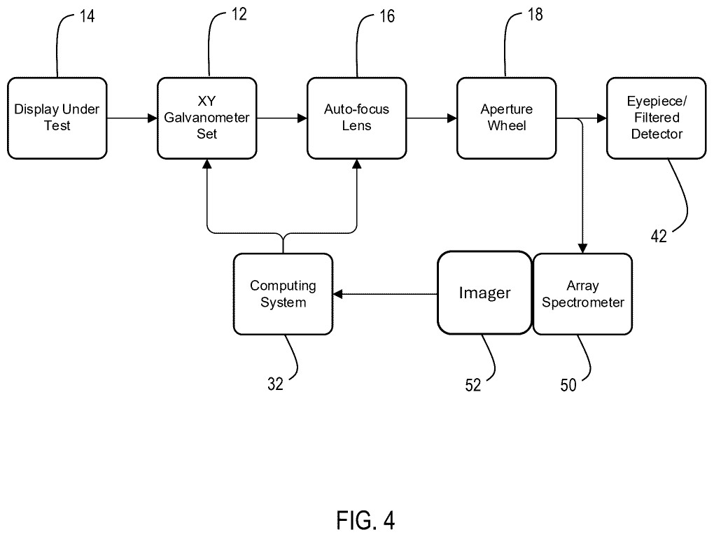

As in known in the art, XY galvanometer set 12 typically includes two motors actuated by a moving magnet with a position detector. The two mirrors are positioned along the optical axis X-X, with one mirror deflecting the illumination from the near eye display in an X dimension and the other mirror deflecting the beam in a Y dimension. Referring to FIG. 4, each mirror of XY galvanometer set 12 is controlled by a programmable controller 32, i.e., a computing system, that is programmed to the drive mirrors and correct for distortions in XY galvanometer set such as by selectively operating computer-driven servos coupled to the mirrors. It should be recognized that controller 32 may include a process with associated digital storage media that stores a lookup table to provide correction values for the angles of the mirrors. Controller 32 may also be used to automatically control auto-focus mechanism 16. Auto-focus mechanism 16 may comprise a standard auto-focus assembly, such as a fixed lens on a movable stage (e.g. moved by a voice coil motor), or fixed lens paired with a tunable focal length lens (e.g. liquid crystal or electro-whetting). Aperture wheel 18 of metrology instrument 10 may comprise circular and slit apertures (e.g., a pinhole on an aperture wheel) to further reduce the measurement field angle and block out-of-focus illumination. A front surface mirror may be used to reflect a portion of the light.

Metrology instrument 10 further comprises an eyepiece and/or a filtered detector 42 that may used to help orient metrology instrument and view scanning performed by XY galvanometer set 12. Metrology instrument 10 may thus optionally include additional lenses to relay the focused light to an observer. In another embodiment, metrology instrument 10 may include at least one filter, such as a CIE spectral luminous efficiency function and/or CIE color matching functions (e.g., using a color filter wheel) and a photodetector (e.g., avalanche photodiode).

As noted above, metrology instrument 10 additionally comprises an array spectrometer 50 having a spectrograph that can disperse light into narrow bandwidths, such as a slit with prism or diffraction grating and focusing elements, that is positioned and aligned to receive the output beam of XY galvanometer set 12 after it passed through autofocus mechanism, 16 and the selected aperture of aperture wheel 18. Array spectrometer 50 includes an imager 52, such as a charge-coupled device, having an array of pixels on which the spectral image received from XY galvanometer set 12 may be focused so that the characteristics of the spectral image can be digitally assessed.

Referring to FIG. 5, metrology instrument 10 may be positioned with XY galvanometer set 12 at the eye point 60 of near eye display 14 under test, i.e., where the virtual image field of view produced by near eye display 14 reflecting off of a windshield 62 is viewed uniformly (also referred to as the eyebox). When metrology instrument 10 is actuated, controller 32 executes a scanning process to rapidly scan a focal point of the field of view at multiple virtual image distances (as seen through the near eye display optics), with the readings collected by spectrometer 50. Each reading corresponds to a field point in the field of view, with the readings collected sequentially to form an image of the output of near eye display 14. The measured image may then be used to calculate two-dimensional luminance, chromaticity, spectral radiance, spatial contrast, and resolution.

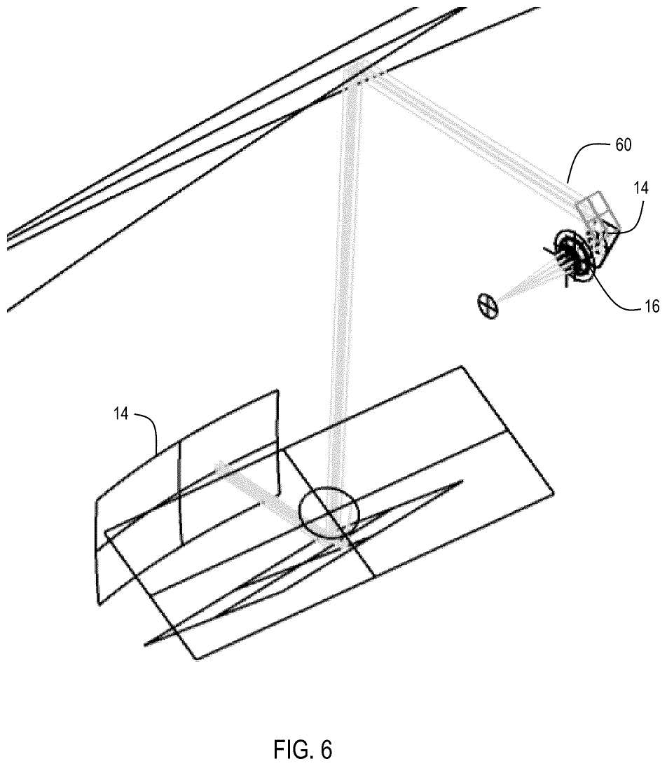

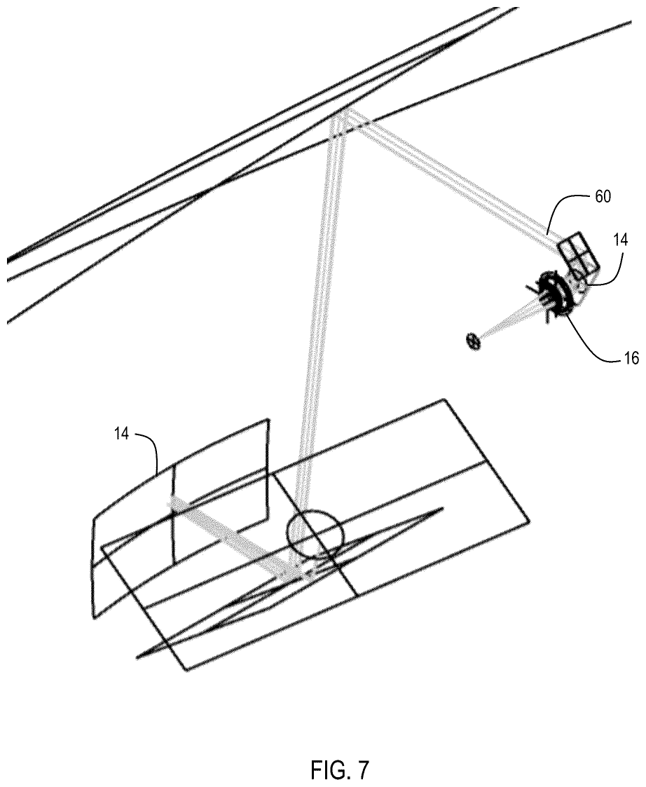

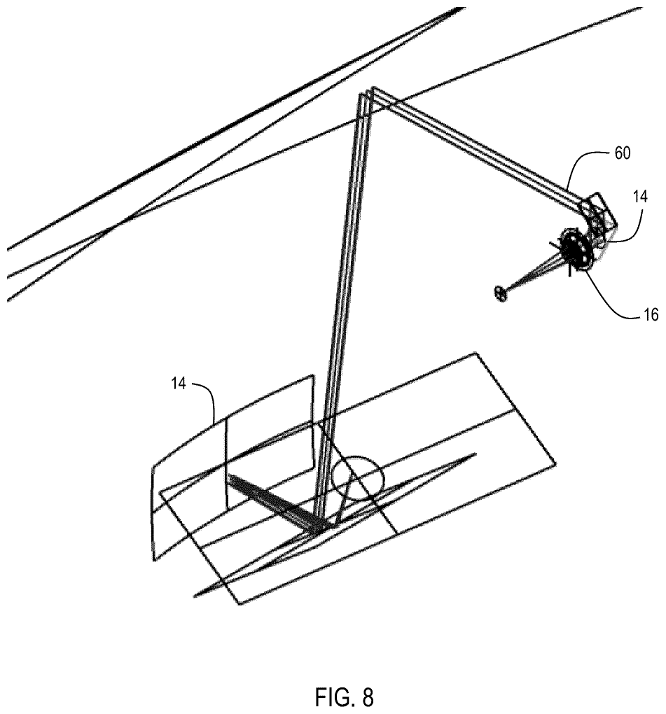

Referring to FIGS. 6 through 8, metrology instrument 10 may use XY galvanometer set 12 to scan a focal point from the illumination of near eye display 14 under testing in directions that are perpendicular to illumination across the field of view. The XY field angles are deflected to an on-axis field angle that is focused independent of magnification due to the focal length of the display under test. Autofocus mechanism 16 enables multiple virtual image distances. Several measurements are enabled once the focal point from the illumination is refocused, including 2D luminance, chromaticity, spectral radiance, spatial contrast, and resolution.

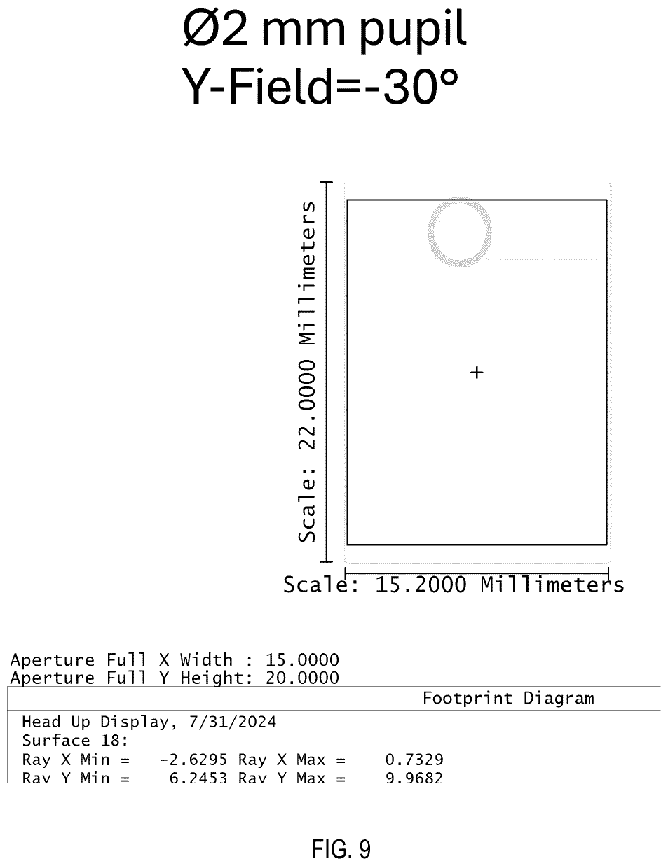

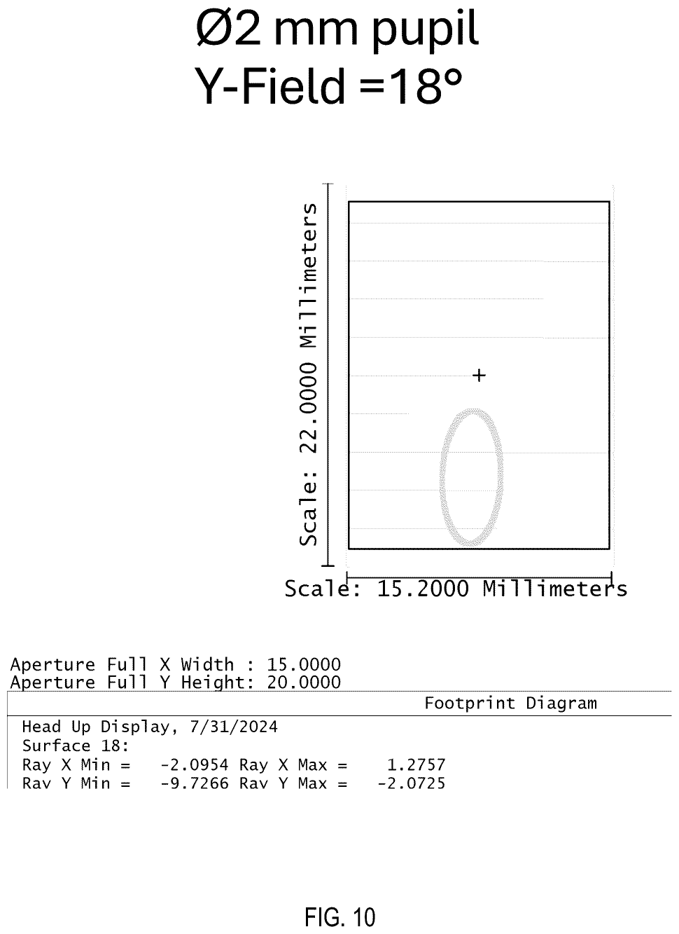

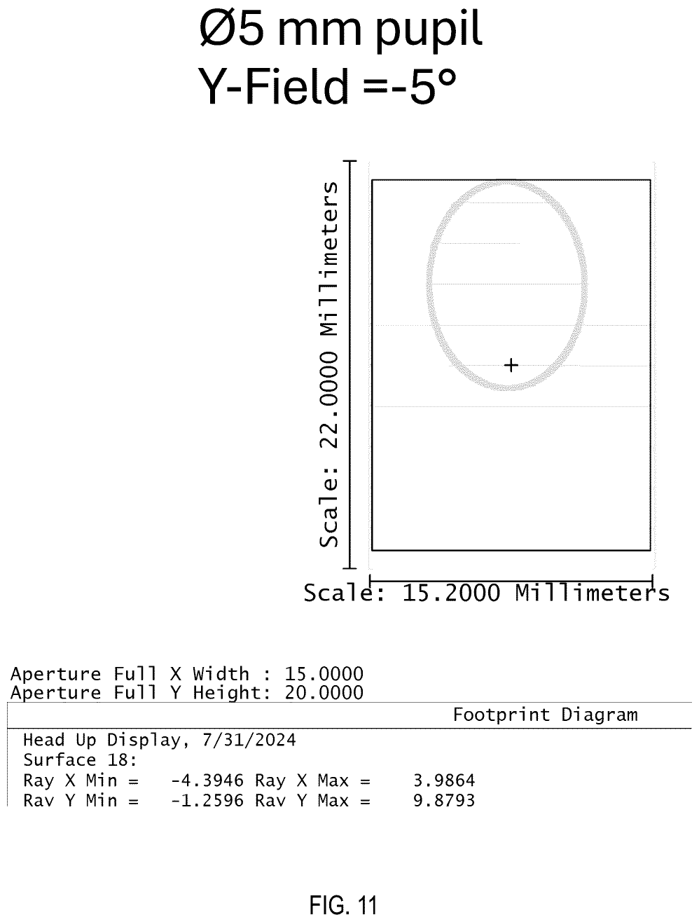

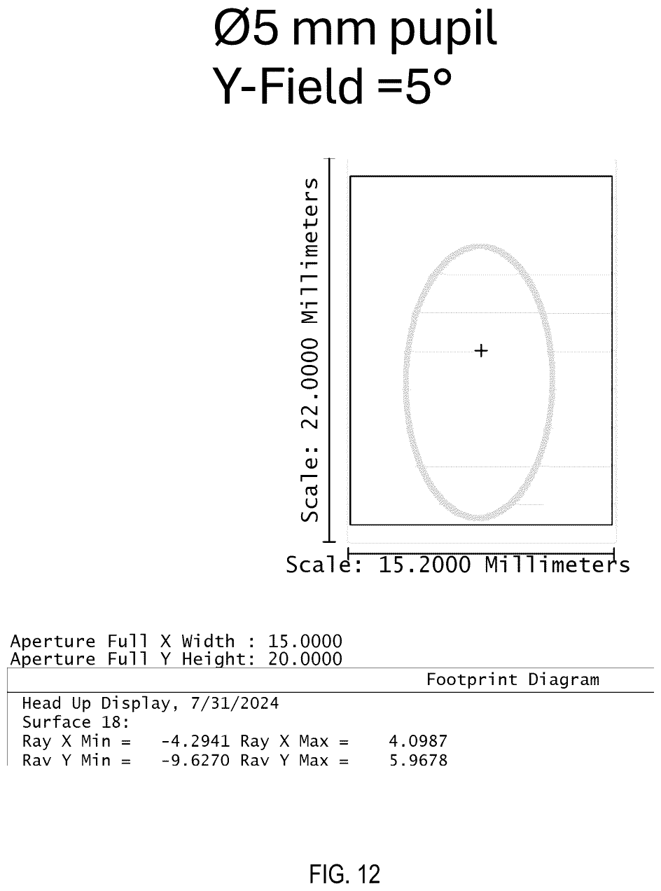

Referring to FIGS. 9 through 12, the extent to which the XY field angles are deflected is limited by the beam diameter (e.g. pupil diameter) in one axis (e.g. the vertical axis or Y-Field). The horizontal axis is limited by the mechanical range of scanning (X-Field=+/−40 degrees). AR-HUD applications require the vertical full FOV to be approximately 6.6 degrees and 20 degrees for the horizontal full FOV. As seen in FIGS. 9 through 12, metrology instrument 10 may meet or exceed these requirements.

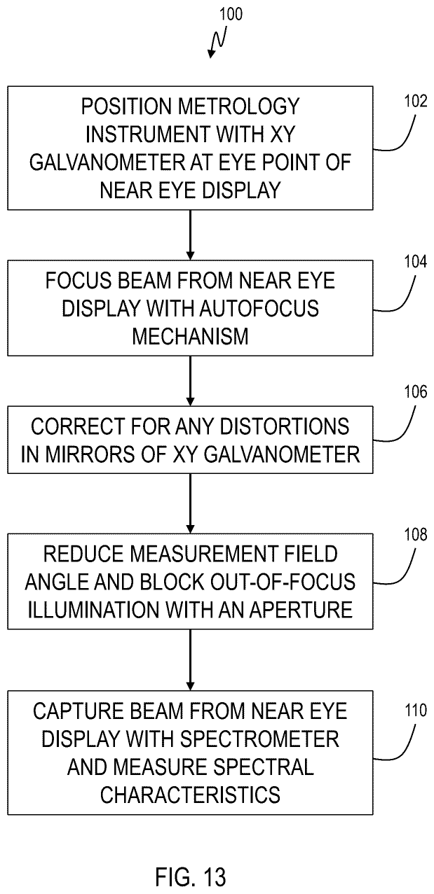

Referring to FIG. 13, metrology instrument 10 may thus be used to implement a method 100 of performing photometric measurements of a near eye display. First, XY galvanometer 12 of metrology instrument 10 is positioned at an eye point of the near eye display 102. Next, the beam is focused with focused with an autofocus mechanism 104 and any distortions are corrected 106. The measurement field angle is the reduced and any out-of-focus illumination blocked with an aperture 108. Finally, the beam is captured with spectrometer 50 so that an image of the near field display can be constructed and a plurality of spectral characteristics of the image represented by multiple scans can be measured 110.

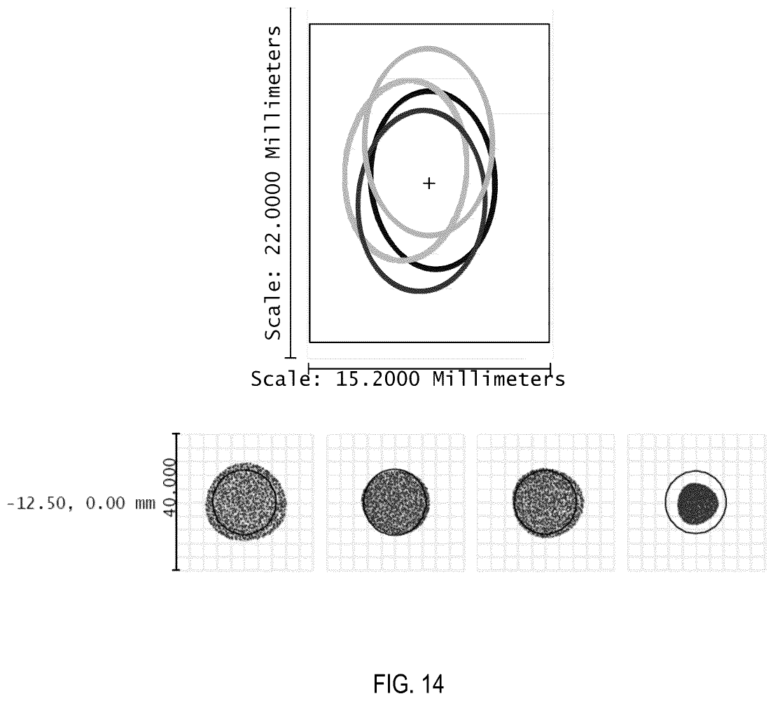

Referring to FIG. 14, XY galvanometer set 12 with spectrometer 50 may experience a pupil shift between the two mirrors as seen in in the pupil for the different field angles at the second mirror (top) and a configuration spot diagram with focus compensation for each field point (bottom). In exchange for the pupil shift, the off-axis rays that were once problematic are simplified to an on-axis optimization for the objective with a different focus for each field point. Diffraction-limited performance is obtainable with the size of the mirror and its range of motion as the only constraints for pupil diameter and field of view, respectively. This effect may be remedied by using three mirrors (rather than two) to ensure that the pupils of the XY galvanometer set 12 are coincident. The first two mirrors are moved in the same plane so that the beam rotates about a pupil centered on the third mirror, which rotates in the orthogonal direction. In this manner, the pupil remains substantially stationary over a large scan range. The virtual conjugate arrangement of these mirrors results in a total scan range of 32.2°, compared to +/−40° for XY galvanometer set 12 with two mirrors.

What is claimed is:

1. A metrology instrument for a near eye display, comprising
an XY galvanometer oriented along an optical axis to controllably deflect a beam traveling along the optical axis in an X dimension and in a Y dimension;
an autofocus mechanism positioned along the optical axis;
a controller coupled to the pair of motors that is programmed to correct for any distortions in the XY galvanometer and to control the autofocus mechanism;
at least one aperture positioned along the optical axis and oriented to reduce a measurement field angle and to block any out-of-focus illumination;
an eyepiece positioned along the optical axis; and
a spectrograph positioned along the optical axis for measuring a plurality of spectral characteristics of the beam.

2. The metrology instrument of claim 1, wherein the spectrograph includes an imager for capturing a digital image of the beam.

3. The metrology instrument of claim 2, wherein the XY galvanometer has a field of view of at least twenty degrees along a horizontal axis.

4. The metrology instrument of claim 2, wherein the XY galvanometer has a field of view of at least 6.6 degrees along a vertical axis.

5. A method of performing photometric measurements of a near eye display, comprising the steps of:
positioning an XY galvanometer at an eye point of the near eye display to receive a beam received along an optical axis;
using a controller to deflect the beam in an X dimension;
using the controller to deflect the beam in a Y dimension;
using the controller to correct for any distortions in the XY galvanometer;
focusing the beam with an autofocus mechanism;
reducing a measurement field angle and blocking any out-of-focus illumination of the beam with an aperture; and
capturing the beam with spectrograph to measure a plurality of spectral characteristics of the beam.

6. The method of claim 5, further comprising the step of capturing a digital image of the beam with an imager associated with the spectrograph.

7. The method of claim 6, wherein the XY galvanometer has a field of view of at least twenty degrees along a horizontal axis.

8. The method of claim 6, wherein the XY galvanometer has a field of view of at least 6.6 degrees along a vertical axis.
